(19) United States
(12) Patent Application Publication
(10) Pub. No.: US 2026/0282342 A1
(43) Pub. Date: Sep. 17, 2026

(54) SEMICONDUCTOR DEVICE AND PREPARATION METHOD THEREFOR, AND MEMORY AND ELECTRONIC DEVICE

(71) Applicant: BEIJING SUPERSTRING ACADEMY OF MEMORY TECHNOLOGY, Beijing (CN)

(72) Inventors: Jingjing Duan, Beijing (CN); Bowen Dong, Beijing (CN); Wenhua Gui, Beijing (CN); Xuezheng Ai, Beijing (CN); Shaohua Wang, Beijing (CN); Guilei Wang, Beijing (CN); Xiangsheng Wang, Beijing (CN); Chao Zhao, Beijing (CN)

(73) Assignee: BEIJING SUPERSTRING ACADEMY OF MEMORY TECHNOLOGY, Beijing (CN)

(21) Appl. No.: 19/168,974

(22) PCT Filed: Oct. 20, 2023
(86) PCT No.: PCT/CN2023/125655

§ 371 Date: Sep. 25, 2025

(30) Foreign Application Priority Data
Apr. 17, 2023 (CN) 202310409079.2

(51) Int. Cl. H10B 12/00; H10D 30/67; H10W 20/44

(52) U.S. Cl. CPC H10B 12/488; H10B 12/05; H10B 12/482; H10D 30/6728; H10D 30/6736; H10D 30/6739; H10D 30/6755; H10D 30/6757; H10W 20/4405; H10W 20/4424; H10W 20/4441

(57) ABSTRACT

A semiconductor device and a preparation method therefor, and a memory and an electronic device are provided. The preparation method comprises: providing a substrate, and forming a stacked structure on the substrate, wherein the stacked structure comprises a dielectric layer and a sacrificial layer, which are alternately stacked in the thickness direction of the substrate; on the basis of the stacked structure, forming initial semiconductor pillars which are arranged at intervals in a first direction, and reference word line trenches which are arranged at intervals in the first direction, wherein each initial semiconductor pillar comprises a dielectric portion and a sacrificial portion, which are alternately stacked in the thickness direction; removing the sacrificial portion, and replacing the sacrificial portion with an electrically conductive portion; and forming a target word line trench on the basis of the reference word line trenches.

### CROSS-REFERENCE TO RELATED APPLICATIONS

The present disclosure is a U.S. National Phase Entry of International Application PCT/CN2023/125655 having an international filing date of Oct. 20, 2023, which claims priority to Chinese patent application No. 202310409079.2, filed to the CNIPA on Apr. 17, 2023 and entitled “Semiconductor Device and Preparation Method Therefor, and Memory and Electronic Device”, the entire contents of the above-identified applications are incorporated by reference in the present disclosure.

### TECHNICAL FIELD

The present disclosure relates to the technical field of integrated circuits, in particular to a semiconductor device, a method for preparing the semiconductor device, a memory, and an electronic device.

### BACKGROUND

With the development of science and technology, demands for memory devices in semiconductor field are increasing day by day. Traditional planar memory devices have difficulty in meeting requirements of further miniaturization of integrated circuits, and 3D memory is becoming a focus of research for the public.

Vertical oxide channel 3D memory device is a new type of three-dimensional stacked memory device, in which a plurality of layers of transistor devices are connected by using channel materials, thereby achieving improved storage density. However, the preparation of vertical oxide channel 3D memory devices is difficult, so it is urgent to provide a method for preparing a semiconductor device to optimize its preparation process and improve its yield.

### SUMMARY

According to various embodiments of the present disclosure, a semiconductor device, a method for preparing the semiconductor device, a memory, and an electronic device are provided.

According to some embodiments, an aspect of the present disclosure provides a method for preparing a semiconductor device, including: providing a substrate and forming a stacked structure on the substrate, wherein the stacked structure includes dielectric layers and sacrificial layers alternately stacked in a thickness direction of the substrate, and the dielectric layer is adjacent to the substrate; forming a plurality of initial semiconductor pillars arranged at intervals in a first direction based on the stacked structure, and forming a plurality of reference word line trenches arranged at intervals in the first direction; wherein an initial semiconductor pillar of the plurality of initial semiconductor pillars includes dielectric portions and sacrificial portions alternately stacked in the thickness direction, and a reference word line trench of the plurality of reference word line exposes a part of the substrate; removing the sacrificial portion and replacing the sacrificial portion with a conductive portion; wherein the dielectric portions and the conductive portions alternately stacked in the thickness direction are used to form a target semiconductor pillar; and forming a target word line trench based on the reference word line trench to form a target word line structure within the target word line trench.

In some embodiments, the initial semiconductor pillar extends in a second direction; wherein the second direction intersects the first direction; forming the initial semiconductor pillars and the reference word line trenches includes: forming the plurality of initial semiconductor pillars arranged at intervals in the first direction based on the stacked structure; laterally etching the initial semiconductor pillar in the second direction such that a side of the sacrificial portion in the second direction exceeds a side of the dielectric portion in the second direction; forming a support layer on a surface on a side of the initial semiconductor pillar in the second direction; and forming the reference word line trench within the initial semiconductor pillar.

In some embodiments, forming the initial semiconductor pillars and the reference word line trenches includes: forming the plurality of reference word line trenches arranged in the first direction within the stacked structure; laterally etching the stacked structure in a second direction such that a side of the sacrificial layer in the second direction exceeds a side of the dielectric layer in the second direction; forming a support layer on a surface on a side of the stacked structure in the second direction; and forming the plurality of initial semiconductor pillars arranged at intervals in the first direction based on the stacked structure, the reference word line trenches being located within the initial semiconductor pillars; wherein the second direction intersects the first direction.

In some embodiments, a material of the dielectric portion includes an oxide; a material of the sacrificial portion is selected from nitride, polysilicon, and combinations thereof; a material of the conductive portion is selected from copper, tungsten, aluminum, copper alloy, and combinations thereof.

In some embodiments, a word line material layer is formed in the reference word line trench; forming the target word line trench further including: removing the word line material layer; and etching the dielectric portion and the conductive portion in the first direction and the second direction via the reference word line trench to form the target word line trench; the target word line trench includes a plurality of gate trenches arranged in sequence in the thickness direction and interconnected.

In some embodiments, forming the target word line structure includes: sequentially forming a gate structure and a target channel layer in the gate trench, wherein the target word line structure includes a plurality of the gate structures arranged in sequence in the thickness direction; wherein the gate structure includes a protrusion portion and a horizontal portion connected to a bottom surface of the protrusion portion, wherein the protrusion portion penetrates through the conductive portion directly above the protrusion portion in the thickness direction, the horizontal portion is positioned between conductive portions adjacent in the thickness direction and connected to the protrusion portion directly above the horizontal portion; the target channel layer circumferentially surrounds an outer side wall of the protrusion portion.

In some embodiments, the gate structure includes a gate conductive layer and a gate dielectric layer, and the gate conductive layer includes a gate protrusion portion and a gate horizontal portion; the gate dielectric layer is located on a target side surface of the gate conductive layer, and the target side surface includes at least an outer side wall of the gate protrusion portion.

In some embodiments, an inner surface of the target word line trench is further covered with an initial channel layer; a method for forming the target channel layer includes: removing parts of the initial channel layer located on opposite sides of the horizontal portion in the first direction, and forming an intermediate channel layer with a remaining initial channel layer; removing parts of the intermediate channel layer located on opposite sides of the horizontal portion in the second direction, and forming the target channel layer with a remaining intermediate channel layer; wherein the second direction intersects the first direction.

In some embodiments, forming the intermediate channel layer includes: forming a first trench and a second trench extending in the second direction in the stacked structure, and removing parts of the initial channel layer located on opposite sides of the horizontal portion in the first direction, wherein the first trench and the second trench are located on opposite sides of the gate conductive layer in the first direction, a distance between the first trench and the second trench in the first direction is smaller than a length of the horizontal portion in the first direction and larger than a length of the protrusion portion in the first direction, and a remaining initial channel layer forms the intermediate channel layer.

In some embodiments, the first trench and the second trench are formed by a dry etching process.

In some embodiments, forming the target channel layer includes: forming a third trench and a fourth trench extending in the first direction in the dielectric portion on opposite sides of the gate conductive layer in the second direction to expose the intermediate channel layer on opposite sides of the horizontal portion in the second direction; a spacing between the third trench and the fourth trench in the second direction is equal to a target spacing, and the target spacing is a spacing between outer side walls of the intermediate channel layer on opposite sides of the horizontal portion in the second direction; and etching and removing a part of the intermediate channel layer via the third trench and the fourth trench, and forming the target channel layer with a remaining intermediate channel layer.

In some embodiments, the third trench and the fourth trench are formed by a dry etching process; a part of the intermediate channel layer is etched and removed via the third trench and the fourth trench using a wet etching process.

In some embodiments, after forming the conductive portion and before forming the target word line trench, further includes: forming a capacitor structure at a first end of the conductive portion in the second direction, wherein the capacitor structure surrounds the conductive portion.

In some embodiments, a second end of the conductive portion opposite to the first end in the second direction is further formed with a bit line structure, conductive portions adjacent in the first direction share the bit line structure, and bit line structures adjacent in the thickness direction are insulated from each other; a side of the bit line structure in the first direction is further formed with a common bit line extending in the second direction, and common bit lines adjacent in the thickness direction are insulated from each other; after forming the target word line structure, further including: forming a metal contact layer on a top of the capacitor structure, a top of the target word line structure, and a top of the common bit line.

According to some embodiments, another aspect of the present disclosure provides a semiconductor device prepared by the method for preparing a semiconductor device according to any one of the embodiments of the present application, wherein the semiconductor device includes a substrate, a plurality of target semiconductor pillars arranged in a first direction, and a target word line structure; the target semiconductor pillar includes dielectric portions and conductive portions alternately stacked in a thickness direction of the substrate; wherein the dielectric portion is adjacent to the substrate; the target word line structure is located within the target semiconductor pillar and its bottom surface is adjacent to the substrate.

In some embodiments, a side of the conductive portion in the second direction exceeds a side of the dielectric portion in the second direction; wherein the second direction intersects the first direction; the semiconductor device further including a support layer located on a surface on a side of the target semiconductor pillar in the second direction.

In some embodiments, a material of the dielectric portion includes an oxide; a material of the conductive portion is selected from copper, tungsten, aluminum, copper alloy, and combinations thereof.

In some embodiments, the target word line structure includes a plurality of gate structures arranged in sequence in the thickness direction; a gate structure of the plurality of gate structures includes a protrusion portion and a horizontal portion connected to a bottom surface of the protrusion portion, wherein the protrusion portion penetrates through the conductive portion directly above the protrusion portion in a thickness direction of the conductive portion, and the horizontal portion is positioned between conductive portions adjacent in the thickness direction and connected to the protrusion portion directly above the horizontal portion.

In some embodiments, the semiconductor device further includes a target channel layer circumferentially surrounding an outer side wall of the protrusion portion.

In some embodiments, a bottom surface of the protrusion portion is located in a middle of a top surface of the horizontal portion.

In some embodiments, a thickness of the horizontal portion is greater than a length of the protrusion portion in the second direction.

In some embodiments, a thickness of the horizontal portion is greater than a length of the protrusion portion in the first direction.

In some embodiments, the gate structure includes a gate conductive layer and a gate dielectric layer, and the gate conductive layer includes a gate protrusion portion and a gate horizontal portion; the gate dielectric layer is located on a target side surface of the gate conductive layer, and the target side surface includes at least an outer side wall of the gate protrusion portion.

In some embodiments, the target side surface is an outer side wall of the gate protrusion portion; or an outer side wall of the gate protrusion portion, and at least a part of an outer surface of the gate horizontal portion.

In some embodiments, a material of the gate conductive layer is selected from indium tin oxide, polysilicon, copper, tungsten, aluminum, copper alloy, titanium, titanium nitride, yttrium nitride, tantalum nitride, and combinations thereof.

In some embodiments, a material of the gate dielectric layer is selected from hafnium dioxide, zirconium dioxide, titanium dioxide, aluminum oxide, and combinations thereof.

In some embodiments, a material of the target channel layer is selected from indium gallium zinc oxide, indium zinc oxide, transition metal, transition metal oxide, and combinations thereof.

In some embodiments, the semiconductor device further includes a capacitor structure surrounding the conductive portion.

In some embodiments, the semiconductor device further includes a bit line structure; the bit line structure is located at a second end of the conductive portion in the second direction and extending in the first direction, conductive portions adjacent in the first direction share the bit line structure, and bit line structures adjacent in the thickness direction are insulated from each other.

In some embodiments, the semiconductor device further includes a common bit line located at a side of the bit line structure in the first direction and extending in the second direction, and common bit lines adjacent in the thickness direction are insulated from each other.

In some embodiments, the semiconductor device further includes a metal contact layer located on a top of the capacitor structure, on a top of the target word line structure, and on a top of the common bit line.

According to some embodiments, yet another aspect of the present disclosure provides a memory including two semiconductor devices according to any one of the embodiments of the present application adjacent in a second direction; wherein the two semiconductor devices adjacent in the second direction share a bit line structure.

According to some embodiments, yet another aspect of the present disclosure provides an electronic device including the memory of any one of the embodiments of the present application.

Details of one or more embodiments of the present disclosure are set forth in the following drawings and description. Other features, objects, and advantages of the present disclosure will become apparent from the specification, drawings, and claims.

### BRIEF DESCRIPTION OF DRAWINGS

In order to more clearly illustrate the technical solutions of the embodiments of the present disclosure, the following is a brief description of the accompanying drawings that need to be used in the description of the embodiments. It will be apparent that the accompanying drawings in the following description are only some embodiments of the present disclosure, for those of ordinary skills in the art, accompanying drawings of other embodiments can also be obtained from these accompanying drawings without inventive effort.

FIG. 1 is a schematic flowchart of a method for preparing a semiconductor device according to an embodiment of the present application.

FIGS. 2 to 16 are schematic diagrams of three-dimensional structures, three-dimensional perspective structures, perspective structures of different direction views, and cross-sections in different directions obtained from different steps in the method for preparing a semiconductor device according to different embodiments of the present application.

### DETAILED DESCRIPTION

In order to facilitate understanding of the present application, the present application will be described more fully below with reference to the accompanying drawings. Preferred embodiments of the present application are shown in the accompanying drawings. However, the present application may be implemented in many different forms and is not limited to the embodiments described herein. Instead, these embodiments are provided to make the disclosure of the present application more thorough and comprehensive.

Unless otherwise defined, all technical and scientific terms used herein have the same meaning as commonly understood by those skilled in the art belonging to the technical field of the present application. Terms used herein in the specification of the present application are for the purpose of describing specific embodiments only and are not intended to limit the present application. Terms “and/or” as used herein include any and all combinations of one or more related listed items.

It should be understood that when an element or layer is referred to as “on,” “adjacent to,” “connected to,” or “coupled to” other elements or layers, it may be directly on, adjacent to, connected to, or coupled to the other elements or layers, or intervening elements or layers may be present. Conversely, when an element is referred to as being “directly on,” “directly adjacent to,” “directly connected to,” or “directly coupled to” other elements or layers, there are no intervening elements or layers. It should be understood that although the terms first, second, third, etc. may be used to describe various elements, components, regions, layers, and/or portions, these elements, components, regions, layers, and/or portions should not be limited by these terms. These terms are merely used to distinguish one element, component, region, layer, or portion from another element, component, region, layer, or portion. Thus, a first element, component, region, layer, or portion discussed below may be represented as a second element, component, region, layer, or portion without departing from the teachings of the present application.

Spatial relational terms such as “under,” “below,” “lower,” “beneath”, “above,” “upper” etc. may be used herein for convenience of description to describe one element or feature in relation to other elements or features shown in the drawings. It should be understood that in addition to the orientations shown in the drawings, the spatial relationship terms are intended to include different orientations of the devices in use and operation. For example, if a device in an accompanying drawing is inverted, then an element or feature described as “under” or “below” or “beneath” other elements will be oriented as “above” other elements or features. Accordingly, the exemplary terms “under” and “below” may include both upper and lower orientations. A device may be otherwise oriented (rotated 90 degrees or other orientations) and the spatial descriptors used herein are explained accordingly.

The terms used herein are for the purpose of describing specific embodiments only and are not intended to limiting the present application. As used herein, the singular forms “a,” “an,” and “said/the” are also intended to include the plural forms unless the context clearly dictates otherwise. It should also be understood that the terms “consisting” and/or “including,” when used in this specification, determine the presence of the stated features, integers, steps, operations, elements, and/or components, but do not preclude the presence or addition of one or more other features, integers, steps, operations, elements, components, and/or groups. As used herein, the term “and/or” includes any and all combinations of the relevant listed items.

Embodiments of the application are described herein with reference to cross-sectional views that are schematic diagrams of ideal embodiments (and intermediate structures) of the present application. In this way, variations from the shown shape due to, for example, manufacturing techniques and/or tolerances may be expected. Accordingly, embodiments of the present application should not be limited to the specific shape of the regions shown herein, but include shape deviations due to, for example, manufacturing. The regions shown in the drawings are essentially schematic, and their shapes are not intended to show the actual shapes of the regions of the display device and are not intended to limit the scope of the present application.

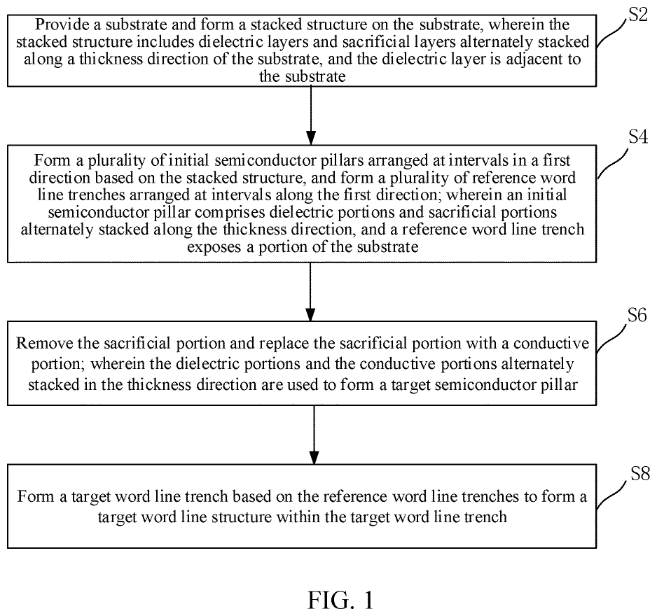

Referring to FIGS. 1-16, it should be noted that the drawings provided in this embodiment only illustrate a basic concept of the present application in a schematic manner, although the drawings only show components related to the present application and are not drawn according to the number, shape and size of the components in actual implementation, the pattern, number and proportion of each component in actual implementation may be arbitrarily changed, and layout patterns of the components may be more complicated.

In memory technology, 3D DRAM devices can realize continuation of Moore's Law. In the absence of Extreme ultraviolet (EUV) lithography machines, they can also increase storage density and achieve further miniaturization of integrated circuit sizes. Vertical oxide channel 3D DRAM device is a novel three-dimensional stacked DRAM device, in which a plurality of layers of transistor devices are connected by using a vertical channel material, so as to improve the storage density. In the related device structure design, it is difficult to etch stacked structures of vertical oxide channel 3D DRAM devices. Especially, the etching of the structure in which dielectric portions and conductive portions are alternately stacked, is not only slow, but also the etching effect is poor. Moreover, the stack mentioned above does not refer to a stacked structure commonly used for etching in a chip factory, and additional setting of etching parameters and other etching preparations are required.

Based on the above-described background technical problems, the present application provides a semiconductor device, a method for preparing a semiconductor device, a memory, and an electronic device, in order to optimize a manufacturing process of a vertical oxide channel 3D DRAM device. The working efficiency and yield of the semiconductor device are improved while the process difficulty is reduced.

As an example, with reference to FIG. 1, an aspect of the present application provides a method for preparing a semiconductor device, which includes following steps:
Step S2: providing a substrate and forming a stacked structure on the substrate, wherein the stacked structure includes dielectric layers and sacrificial layers alternately stacked in a thickness direction of the substrate, and one of the dielectric layers is adjacent to the substrate;
Step S4: forming a plurality of initial semiconductor pillars arranged at intervals in a first direction based on the stacked structure, and forming a plurality of reference word line trenches arranged at intervals in the first direction; wherein one of the initial semiconductor pillars includes dielectric portions and sacrificial portions alternately stacked in the thickness direction, and one of the reference word line trenches exposes a part of the substrate;
Step S6: removing the sacrificial portions and replacing the sacrificial portions with conductive portions; wherein the dielectric portions and the conductive portions alternately stacked in the thickness direction are used to form a target semiconductor pillar; and
Step S8: forming a target word line trench based on the reference word line trench to form a target word line structure within the target word line trench.

In the method for preparing the semiconductor device in the above embodiment, by first forming a stacked structure including dielectric layers and sacrificial layers alternately stacked, then forming a plurality of initial semiconductor pillars and reference word line trenches arranged at intervals in the first direction based on the stacked structure, and then replacing the sacrificial portions with conductive portions, the dielectric portions and conductive portions alternately stacked in the thickness direction are formed to reduce etching difficulty of the initial semiconductor pillars and the reference word line trenches. In the semiconductor preparation process, etching of a structure in which dielectric portions and conductive portions are alternately stacked is not only slow, but also the etching effect is poor, and etching the above structure in a chip factory requires additional setting of etching parameters and other etching preparation work. In the present application, by first forming a stacked structure including alternately stacked dielectric layers and sacrificial layers, etching in the stacked structure and then replacing the sacrificial portions in the stacked structure with conductive portions, the etching effect of the stacked structure can be improved and the etching difficulty can be reduced, in addition, the sacrificial layers can use materials that are easy to be etched or often used in factories, thereby reducing the process cost and improving the performance of the semiconductor device.

As an example, in the embodiment of the present application, the thickness direction is oy direction, the first direction is oz direction, the second direction is ox direction, the AA′ cross-sectional direction is the oz direction, and the BB′ cross-sectional direction is the ox direction.

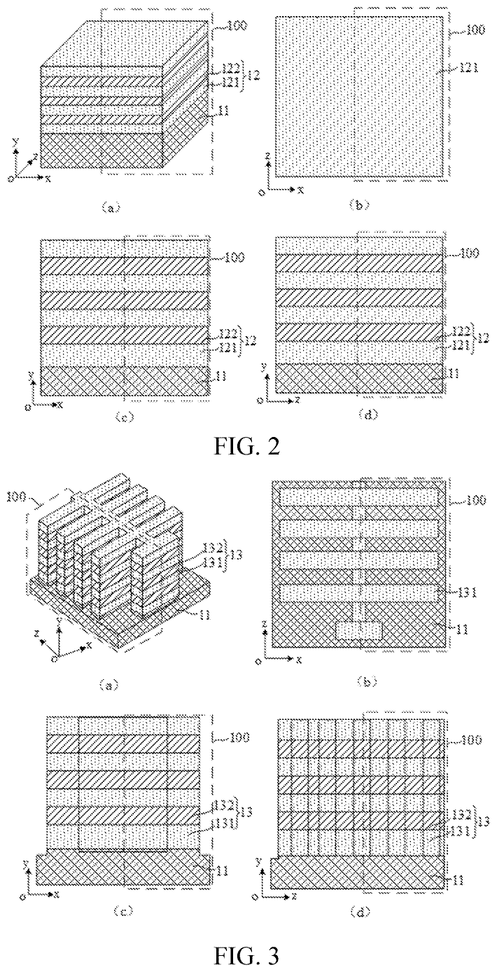

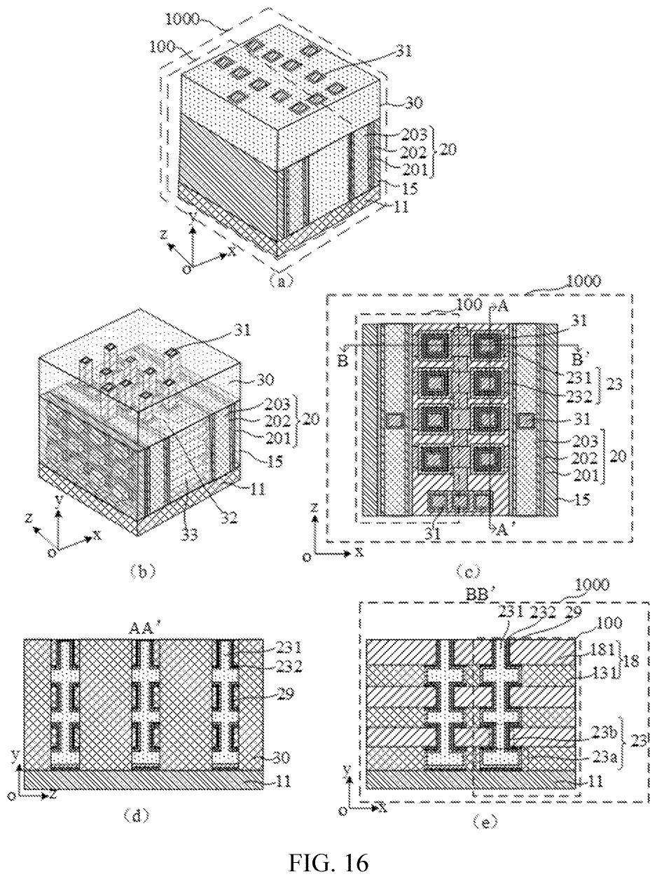

It should be noted that (a) in FIGS. 2 to 16 is a schematic diagram of a three-dimensional structure of a semiconductor device, (b) in FIG. 2, (b) in FIG. 3, and (c) in FIG. 3-16 are schematic top views of corresponding structures, (b) in FIGS. 3-16 are perspective views of corresponding three-dimensional structures, (c)-(d) in FIGS. 2-3 and (d)-(e) in FIGS. 3-15 are schematic perspective structural diagrams of corresponding structures viewed from different directions, and (d)-(e) in FIG. 16 are schematic cross-sectional views of a corresponding structure in the AA′ direction and in the BB′ direction.

In step S2, with reference to step S2 in FIG. 1 and FIG. 2, in the process of preparing the semiconductor device 100, first, a substrate 11 is provided and a stacked structure 12 is formed on the substrate 11. The stacked structure 12 includes dielectric layers 121 and sacrificial layers 122 alternately stacked in the thickness direction (for example, the oy direction) of the substrate 11, and one of the dielectric layers 121 is adjacent to the substrate 11. In a process of manufacturing a vertical channel DRAM device in the present application, the dielectric layers 121 and the sacrificial layers 122 are first stacked and prepared to reduce the etching difficulty based on the stacked structure 12.

As an example, the substrate 11 may be constituted of a semiconductor material, an insulating material, a conductive material, or any combination thereof. The substrate 11 may have a single-layer structure or a multilayer structure. For example, the substrate 11 may be a silicon (Si) substrate, a silicon germanium (SiGe) substrate, a silicon germanium carbon (SiGeC) substrate, a silicon carbide (SiC) substrate, a gallium arsenide (GaAs) substrate, an indium arsenide (InAs) substrate, an indium phosphide (InP) substrate, or other III/V or II/VI semiconductor substrates. Optionally, for example, the substrate 11 may be a layered substrate including, for example, Si/SiGe, Si/SiC, silicon on insulator (SOI), or silicon germanium on insulator. Those skilled in the art can select the type of the substrate 11 according to a type of a transistor formed on the substrate 11, and thus, the type of the substrate 11 should not limit the scope of protection of the present application.

As an example, with continued reference to FIG. 2, a material of the dielectric layers 121 includes an oxide. A material of sacrificial layers 122 is selected from nitride, polysilicon, and combinations thereof. Since the stacked structure of nitride and oxide or polysilicon has low difficulty in etching and is a common structure in processes, a preparation efficiency of the semiconductor device 100 can be improved by stacking the dielectric layers 121 and the sacrificial layers 122. Specifically, specific materials of the dielectric layers 121 and the sacrificial layers 122 may be selected according to the material of the substrate, actual processes, or other factors.

As an example, with reference to step S4 in FIG. 1, FIGS. 2-5, the initial semiconductor pillars 13 extend in the second direction (e.g., the ox direction). The second direction (e.g. the ox direction) intersects the first direction (for example, the oz direction). Forming the initial semiconductor pillars 13 and the reference word line trenches 16 in step S4 includes following steps:
Step S41: forming a plurality of initial semiconductor pillars 13 arranged at intervals in the first direction (e.g., the oz direction) based on the stacked structure 12;
Step S42: laterally etching the initial semiconductor pillars 13 in the second direction (for example, the ox direction) such that a side of a sacrificial portion 132 in the second direction (for example, the ox direction) exceeds a side of a dielectric portion 131 in the second direction (for example, the ox direction);
Step S43: forming a support layer 15 on surfaces the initial semiconductor pillars 13 in the second direction (for example, the ox direction); and
Step S44: forming reference word line trenches 16 in the initial semiconductor pillars 13.

In step S41, with reference to step S4 in FIG. 1 and FIG. 3, a plurality of initial semiconductor pillars 13 arranged at intervals in the first direction (for example, the oz direction) are formed based on the stacked structure 12 to obtain a plurality of active regions.

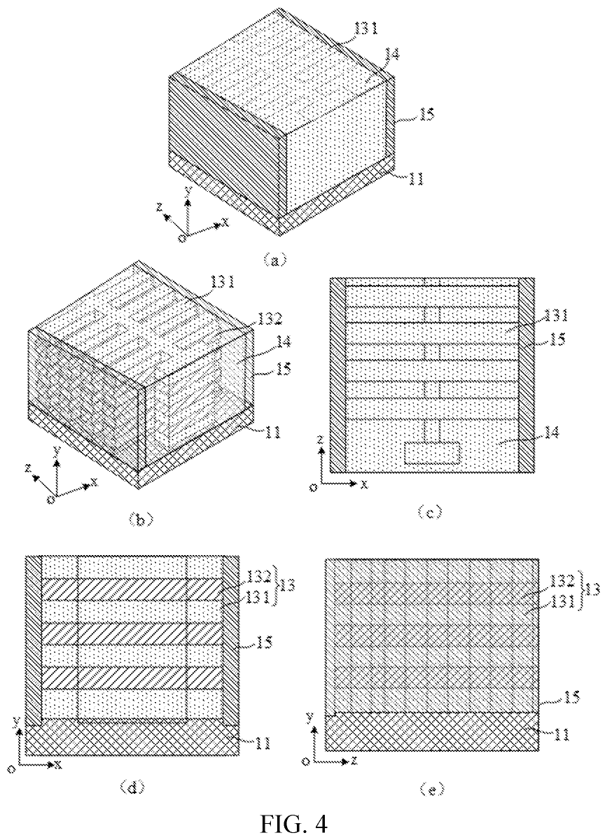

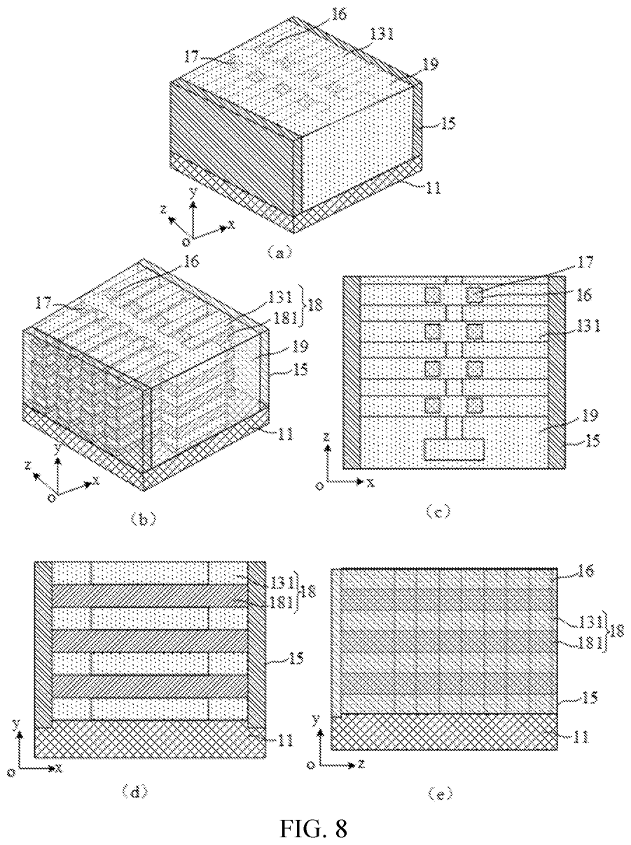

In step S42, with reference to step S4 in FIG. 1 and FIG. 4, a first isolation structure 14 is formed between adjacent initial semiconductor pillars 13 in advance to fill up a gap region in the stacked structure, so as to facilitate subsequent formation of the support layer 15. Then, the initial semiconductor pillars 13 are laterally etched in the second direction (for example, the ox direction) so that the sides of the sacrificial portions 132 in the second direction (for example, the ox direction) exceed the sides of the dielectric portions 131 in the second direction (for example, the ox direction). The above steps provide a basis for subsequent formation of the support layer 15 and replacement of the sacrificial portions 132, the sides of the sacrificial portions 132 in the second direction (for example, the ox direction) exceed the sides of the dielectric portions 131 in the second direction (for example, the ox direction), so that the sides of the sacrificial portions 132 in the second direction (for example, the ox direction) can be positioned within the support layer 15 when the support layer 15 is prepared, so that when the sacrificial portions 132 are replaced by the conductive portions 181 (see FIG. 8), the support layer 15 can provide support for the entire stacked structure 12 and can position a region in which the conductive portions 181 are formed to improve a replacement efficiency and a replacement effect.

In step S43, with continued reference to step S4 in FIG. 1 and FIG. 4, the support layer 15 is formed on surfaces of the initial semiconductor pillars 13 in the second direction (for example, the ox direction), and the support layer 15 is located on surfaces of the dielectric portions 131 and the sacrificial portions 132 in the second direction (for example, the ox direction), and covers ends of the sacrificial portions 132 to provide support for the step of the subsequent replacement of the sacrificial portions 132 with the conductive portions 181, thereby improving a preparation efficiency of the semiconductor device.

As an example, with continued reference to FIG. 4, a material of the first isolation structure 14 may be the same as a material of the dielectric portions 131, both of the materials are dielectric materials to provide insulation and isolation for each semiconductor pillar.

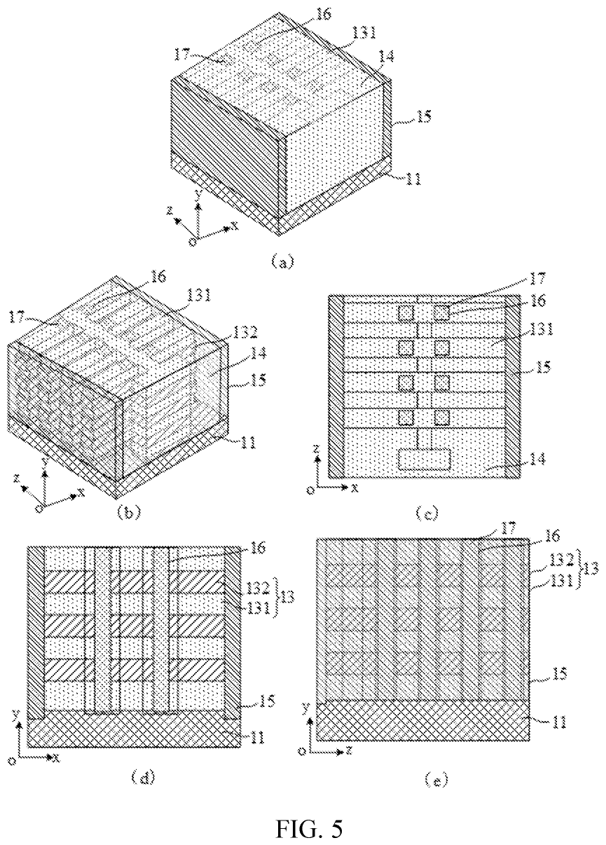

In step S44, with reference to step S4 in FIG. 1 and FIG. 5, a reference word line trench 16 is formed in an initial semiconductor pillar 13, and a word line material layer 17 is formed in the reference word line trench 16, and the word line material layer 17 fills up at least the reference word line trench 16. Specifically, the reference word line trench 16 may be formed using a patterning process and a dry etching process.

As an example, with continued reference to FIG. 5, a dry etching process can be used to etch the initial semiconductor pillars 13 in the thickness direction (e.g. the oy direction) to form the reference word line trench 16, and retain part of sacrificial portions 132 on opposite sides of the reference word line trench 16 in the first direction (for example, the oz direction), that is, in the process of forming an initial trench by dry etching, it is required to ensure that a length of the reference word line trench 16 in the first direction (for example, the oz direction) is smaller than lengths of the sacrificial portions 132 in the first direction (for example, the oz direction). The sacrificial portions 132 retained are used to protect the dielectric material adjacent to the conductive portions 181, i.e., the isolation structure, during subsequent hole expansion, thereby achieving precise hole expansion of the reference word line trench 16 without affecting adjacent other structures. This facilitates the removal of subsequent channel materials to further eliminate parasitic transistors.

It should be noted that, in other embodiments, with reference to step S4 in FIG. 1 and FIGS. 2 to 5, forming the initial semiconductor pillars 13 and the reference word line trenches 16 in step S4 may further include the following steps:
Step S41′: forming a plurality of reference word line trenches 16 arranged in the first direction (for example, the oz direction) in the stacked structure 12;
Step S42′: laterally etching the stacked structure 12 in the second direction (e.g. the ox direction) such that sides of the sacrificial layers 122 in the second direction (e.g. the ox direction) exceed sides of the dielectric layers 121 in the second direction (e.g. the ox direction);
Step S43′: forming a support layer 15 on a surface of the stacked structure 12 in the second direction (for example, the ox direction); and
Step S44′: forming a plurality of initial semiconductor pillars 13 arranged at intervals in the first direction (e.g., the oz direction) based on the stacked structure 12, wherein the reference word line trenches 16 are located in the initial semiconductor pillars 13, and the second direction (e.g. the ox direction) intersects the first direction (for example, the oz direction).

In the above steps S41′ to S44′, the preparation process of the first isolation structure 14 can be omitted, thus costs of materials and masks can be correspondingly reduced, and a preparation sequence of forming the reference word line trenches 16 first and then forming the active regions can further optimize the preparation process of the semiconductor device 100, so as to improve the preparation efficiency of the semiconductor device and reduce the preparation cost.

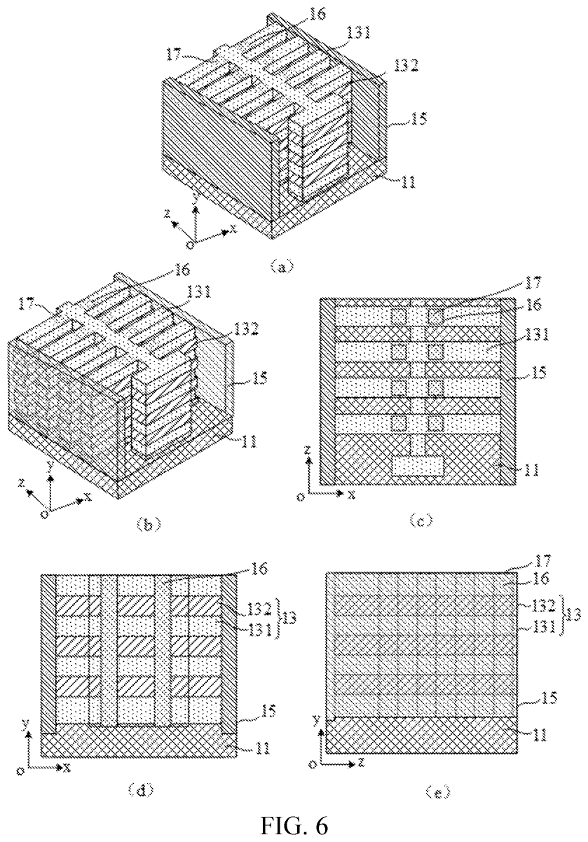

In step S6, with reference to step S6 in FIG. 1 and FIGS. 6, 7, and 8, step S6 includes following steps:
Step S61: removing the first isolation structure 14 to expose surfaces of the initial semiconductor pillar 13 on opposite sides in the first direction (for example, the oz direction);
Step S62: removing the sacrificial portions 132 based on the exposed surfaces of the initial semiconductor pillars 13; and
Step S63: forming the conductive portions 181 in a region occupied by the sacrificial portions 132 before the sacrificial portions 132 are removed, that is, replacing the sacrificial portions 132 with the conductive portions 181.

In step S61, with reference to FIG. 6, two surfaces of an initial semiconductor pillar 13 opposite in the first direction (for example, the oz direction) are exposed, that is, two surfaces of a sacrificial portion 132 opposite in the first direction (for example, the oz direction) are exposed in preparation for etching the sacrificial portion 132.

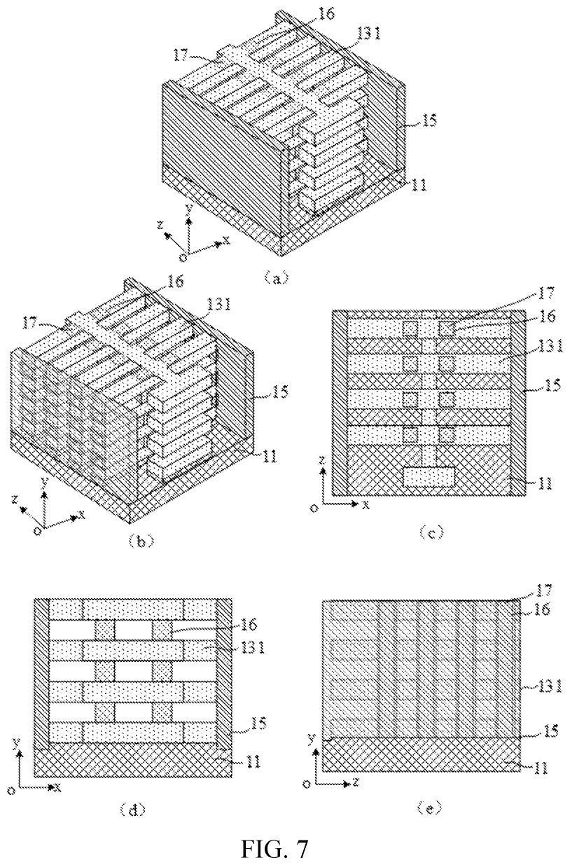

In step S62, with reference to FIG. 7, the sacrificial portion 132 is etched via the exposed surfaces of the sacrificial portion 132 by a wet etching process to completely remove the sacrificial portion 132.

In step S63, with reference to FIG. 8, based on the support and positioning of the support layer 15, the conductive portions 181 are formed in the region occupied by the sacrificial portions 132 before the sacrificial portions 132 are removed, and the conductive portions 181 and the dielectric portions 131 alternately stacked form the target semiconductor pillar 18. Since the support layer 15 can provide support during the preparation of the conductive portions 181, a preparation efficiency of the conductive portions 181 is further improved, and a preparation yield of the semiconductor device 100 is improved.

As an example, with continued reference to FIG. 8, a second isolation structure 19 is formed in a gap between adjacent target semiconductor pillars 18. A material of the second isolation structure 19 may be the same as the material of the dielectric portions 131, that is, both of the materials are dielectric materials, to provide insulation and isolation for each target semiconductor pillar 18.

As an example, with continued reference to FIGS. 2-5, the material of the dielectric portions 131 includes an oxide. The material of the sacrificial portion s132 is selected from nitride, polysilicon, and combinations thereof. The material of the conductive portions 181 is selected from copper, tungsten, aluminum, copper alloy, and combinations thereof. Specifically, the specific material of the conductive portions 181 can be selected according to different actual process factors. Since the stacked structure of the conductive portions 181 and the dielectric portions 131 increases etching difficulty and reduces etching efficiency, in the present application, the stacked structure 12 is first formed by using the sacrificial portions 132 and the dielectric portions 131, and after the active regions and the reference word line trenches 16 are etched, the sacrificial portions 132 are replaced with the conductive portions 181 required by the semiconductor device, and the support layer 15 is used to support the replacement process to achieve the replacement of the sacrificial portions 132 with the conductive portions 181, thereby improving the preparation efficiency of the semiconductor device.

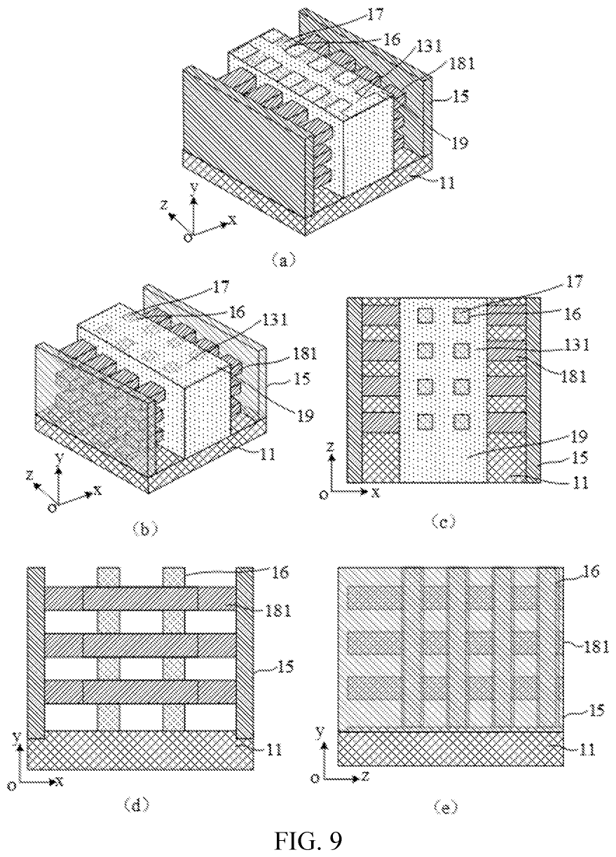

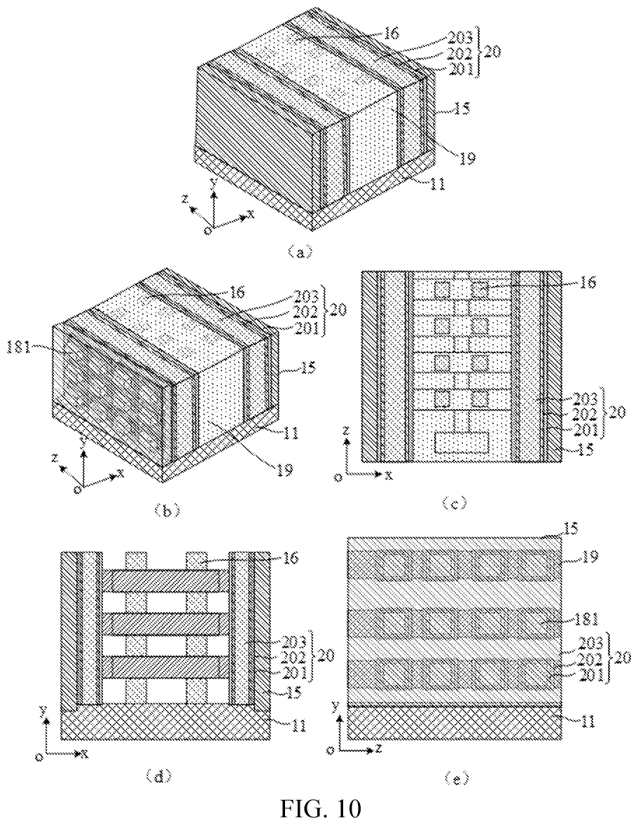

As an example, with reference to FIGS. 9 and 10, after the conductive portions 181 are formed in step S6 and before forming the target word line trench 22 in step S8, the method further includes following steps:
Step S7: forming a capacitor structure 20 on first ends of the conductive portions 181 in the second direction (for example, the ox direction), wherein the capacitor structure 20 is positioned between the support layer 15 and the target semiconductor pillar 18, and surrounds the conductive portions 181.

As an example, with continued reference to FIGS. 9 and 10, forming the capacitor structure 20 in step S7 includes the following steps:
Step S71: removing materials of first ends of the dielectric portions 131 and the second isolation structure 19 in the second direction (for example, the ox direction) to expose outer surfaces of the first ends of the conductive portions 181 in the second direction (for example, the ox direction); and
Step S72: forming a capacitor structure 20 on the first ends of the conductive portions 181 in the second direction (for example, the ox direction), wherein the capacitor structure 20 is positioned between the support layer 15 and the target semiconductor pillars 18, and surrounds the conductive portions 181.

In step S71, with reference to FIG. 9, materials of the first ends of the dielectric portion 131 and the second isolation structure 19 in the second direction (for example, the ox direction) are removed to expose the outer surfaces of the first ends of the conductive portions 181 in the second direction (for example, the ox direction), thereby providing a space for preparation of the capacitor structure 20.

As an example, with continued reference to FIG. 10, step S72 may include following steps:
Step S721: forming a first electrode layer 201 surrounding the conductive portions 181 at the first ends of the conductive portions 181 in the second direction (for example, the ox direction);
Step S722: forming an intermediate dielectric layer 202 on a surface of the first electrode layer 201;
Step S723: filling a second electrode layer 203 between the support layer 15 and the target semiconductor pillars 18, wherein the second electrode layer 203 is located on a surface of the intermediate dielectric layer 202 at the same time, and the first electrode layer 201, the intermediate dielectric layer 202, and the second electrode layer 203 together constitute the capacitor structure 20.

In step S721, with continued reference to FIG. 10, the first electrode layer 201 surrounding the conductive portions 181 is formed at the first ends of the conductive portions 181 in the second direction (for example, the ox direction), and the first electrode layer 201 is located on the outer surfaces of the conductive portions 181 between the support layer 15 and the target semiconductor pillars 18. Specifically, a material of the first electrode layer 201 is selected from doped silicon, polysilicon, copper, tungsten, aluminum, copper alloy, titanium, titanium nitride, yttrium nitride, and combinations thereof.

In step S722, with continued reference to FIG. 10, the intermediate dielectric layer 202 is formed on the surface of the first electrode layer 201. Specifically, a material of the intermediate dielectric layer 202 is selected from aluminum oxide, zirconium oxide, and combinations thereof. The intermediate dielectric layer 202 may also include other insulating materials having a higher dielectric constant (high-K), such as materials having dielectric constants greater than 3.9.

In step S723, with continued reference to FIG. 10, the second electrode layer 203 is filled between the support layer 15 and the target semiconductor pillars 18, the second electrode layer 203 is located on the surface of the intermediate dielectric layer 202 at the same time, and the first electrode layer 201, the intermediate dielectric layer 202, and the second electrode layer 203 together constitute the capacitor structure 20. Specifically, a material of the second electrode layer 203 is selected from doped silicon, polysilicon, copper, tungsten, aluminum, copper alloy, titanium, titanium nitride, yttrium nitride, and combinations thereof.

As an example, with reference to step S8 in FIG. 1, FIG. 9 and FIGS. 11 and 12, a first word line material layer 17 is formed in a reference word line trench 16, and forming the target word line trench 22 in step S8 further includes following steps:
Step S81: removing the first word line material layer 17; and
Step S82: etching the dielectric portions 131 and the conductive portions 181 in the first direction (for example, the oz direction) and the second direction (for example, the ox direction) via the reference word line trench 16 to form the target word line trench 22, wherein the target word line trench 22 includes a plurality of gate trenches arranged sequentially in the thickness direction (e.g., the oy direction) and interconnected.

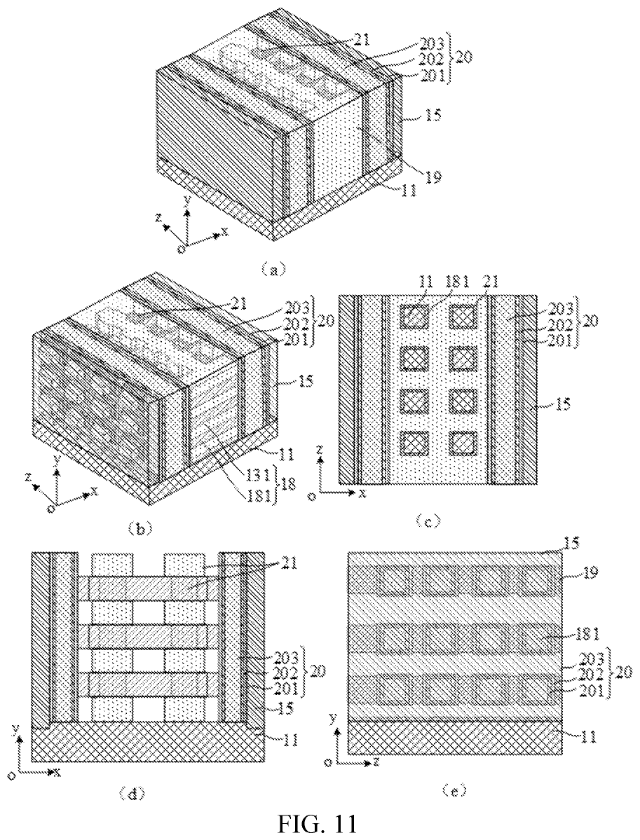

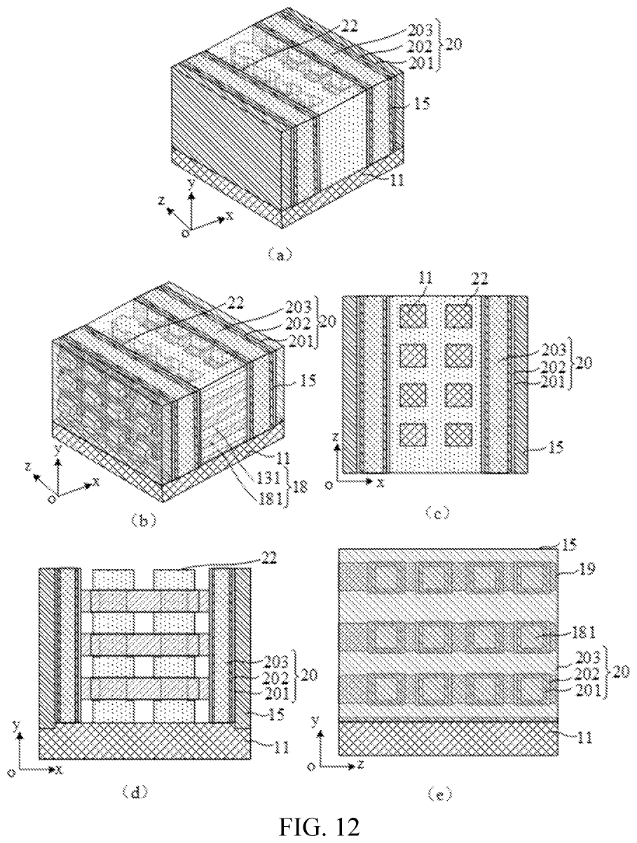

In step S81, with reference to step S8 in FIG. 1, FIG. 11, and FIG. 12, the first word line material layer 17 is removed, such that a gap in communication with the substrate 11 is formed in the reference word line trench 16.

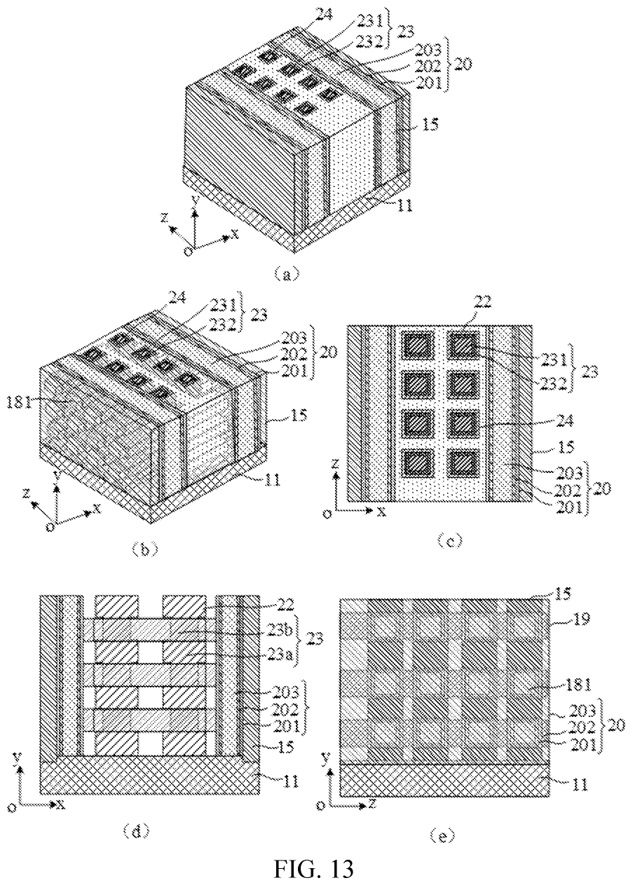

In step S82, with reference to step S8 in FIG. 1 and FIGS. 11 and 12, the dielectric portion 131 and the conductive portion 181 are etched in the first direction (for example, the oz direction) and the second direction (for example, the ox direction) via the reference word line trench 16 to form the target word line trench 22, so as to realize hole expansion of the reference word line trench 16 and facilitate subsequent removal of parasitic transistors. The target word line trench 22 includes a plurality of gate trenches arranged sequentially in the thickness direction (for example, the oy direction) and interconnected, and one of the gate trenches includes two parts having the same or different trench opening sizes for subsequently forming a gate horizontal portion and a gate protrusion portion in a gate conductive layer 231 (see FIG. 13).

As an example, with continued reference to FIG. 11, step S82 includes following steps:
Step S821: etching the dielectric portions 131 in the first direction (for example, the oz direction) and the second direction (for example, the ox direction) via the reference word line trench 16 to perform hole expansion of the reference word line trench 16 adjacent to the dielectric portions 131;
Step S822: etching the conductive portions 181 in the first direction (for example, the oz direction) and the second direction (for example, the ox direction) via the reference word line trench 16 to form the target word line trench 22, the target word line trench 22 includes a plurality of gate trenches arranged sequentially in the thickness direction (for example, the oy direction) and interconnected, and one of the gate trenches includes two parts having different trench opening sizes for subsequent formation of a gate horizontal portion and a gate protrusion portion in the gate conductive layer 231 (see FIG. 13).

In step S821, with continued reference to FIG. 11, the dielectric portions 131 are etched in the first direction (for example, the oz direction) and the second direction (for example, the ox direction) via the reference word line trench 16 to perform hole expansion of the reference word line trench 16 adjacent to the dielectric portions 131 to form an intermediate word line trench 21, so as to expand a trench size of a part of the reference word line trench 16 adjacent to the dielectric portions 131 and facilitate subsequent removal of the channel layer material on this part of structure.

In step S822, with continued reference to FIG. 12, after the dielectric portions 131 are etched, the conductive portions 181 are etched and hole-expanded in order to protect the second isolation structure 19 adjacent to the conductive portions 181 in the first direction (for example, the oz direction) when the dielectric portions 131 are etched, so as to form the target word line trench 22. Since the second isolation structure 19 is located between target semiconductor pillars 18 adjacent in the first direction (for example, the oz direction), and the material of the second isolation structure is the same as the material of the dielectric portions 131, if the dielectric portions 131 and the conductive portions 181 are etched together, the second isolation structure 19 on the opposite sides of the conductive portions 181 in the first direction (for example, the oz direction) will be exposed and etched at the same time. Therefore, the process sequence of etching the dielectric portions 131 first and then etching the conductive portions 181 can effectively protect the second isolation structure 19 adjacent to the conductive portions 181 in the first direction (for example, the oz direction), avoid damage to the second isolation structure 19, and improve the yield of the preparation process.

As an example, with reference to step S8 in FIG. 1 and FIGS. 13-16, forming the target word line structure in step S8 includes following steps:
Step S83: forming gate structures 23 and a target channel layer 29 sequentially in the gate trench, wherein the target word line structure includes a plurality of gate structures 23 sequentially arranged in the thickness direction (for example, the oy direction), one of the gate structures 23 includes a protrusion portion 23b and a horizontal portion 23a connected to a bottom surface of the protrusion portion 23b, the protrusion portion 23b penetrates through a conductive portion 181 directly above it in the thickness direction (for example, the oy direction), the horizontal portion 23a is positioned between conductive portions 181 adjacent in the thickness direction (for example, the oy direction) and connected to the protrusion portion 23b directly above it. The target channel layer 29 circumferentially surrounds an outer side wall of the protrusion portion 23b.

As an example, with reference to FIG. 16, the target channel layer 29 may be located on a target surface of the horizontal portion 23a, and the target surface is an outer surface of the horizontal portion 23a except for its outer side wall.

In step S83, with reference to FIGS. 13 to 16, an initial channel layer 24, a gate dielectric layer 232, and a gate conductive layer 231 are sequentially deposited by an ALD (Atomic Layer Deposition) method, and then the initial channel layer 24, the gate dielectric layer 232, and the gate conductive layer 231 located on the top of the entire semiconductor device 100 are removed by a recessing or a CMP (Chemical Mechanical Polishing) process. The initial channel layer 24, the gate dielectric layer 232, and the gate conductive layer 231 together fill up the gate trench.

The target channel layer 29 formed as described above covers the entire side wall of the protrusion portion 23b and covers a part of the top surface and a part of the bottom surface of the horizontal portion 23a, but does not cover the side wall of the horizontal portion 23a. Therefore, in transistors connected in the thickness direction (e.g. the oy direction) during operation of semiconductor device, although there is an electrical connection between the gate structures 23, there is no parasitic transistor between adjacent transistors because connection between target channel layers 29 of the transistors is broken, thereby reducing a leakage current. Further, since a shape of the target word line trench 22 is the same as that of the gate structure 23, and the gate structure 23 includes the protrusion portion 23b and the horizontal portion 23a connected to the bottom surface of the protrusion portion 23b, therefore, when forming the target channel layer 29, it is convenient to remove a channel layer material on the sidewall of the horizontal portion 23a, that is, the process of forming the target channel layer 29 is relatively simple, so that the device preparation process can be optimized while reducing parasitic transistors, to improve the device performance.

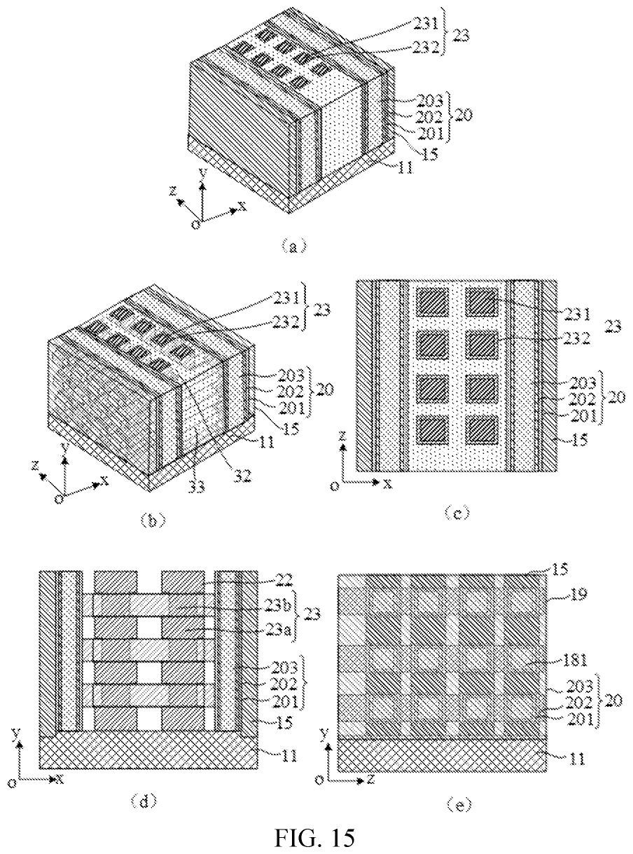

As an example, with continued reference to FIG. 15, the gate structure 23 includes a gate conductive layer 231 and a gate dielectric layer 232, and the gate conductive layer 231 includes a gate protrusion portion and a gate horizontal portion. The gate dielectric layer 232 is located on a target side surface of the gate conductive layer 231, and the target side surface includes at least an outer side wall of the gate protrusion portion. The target channel layer 29 surrounds at least the outer side wall of the gate protrusion portion.

As an example, with reference to FIGS. 13-15, an inner surface of the target word line trench 22 is also covered by an initial channel layer 24, the forming the target channel layer 29 in step S83 includes following steps:
Step S831: removing parts of the initial channel layer 24 located on opposite sides of the horizontal portion 23a in the first direction (for example, the oz direction), and forming an intermediate channel layer by the remaining initial channel layer 24; and
Step S832: removing parts of the intermediate channel layer located on opposite sides of the horizontal portion 23a in the second direction (for example, the ox direction), and forming the target channel layer 29 by the remaining intermediate channel layer, wherein the second direction (e.g. the ox direction) intersects the first direction (for example, the oz direction).

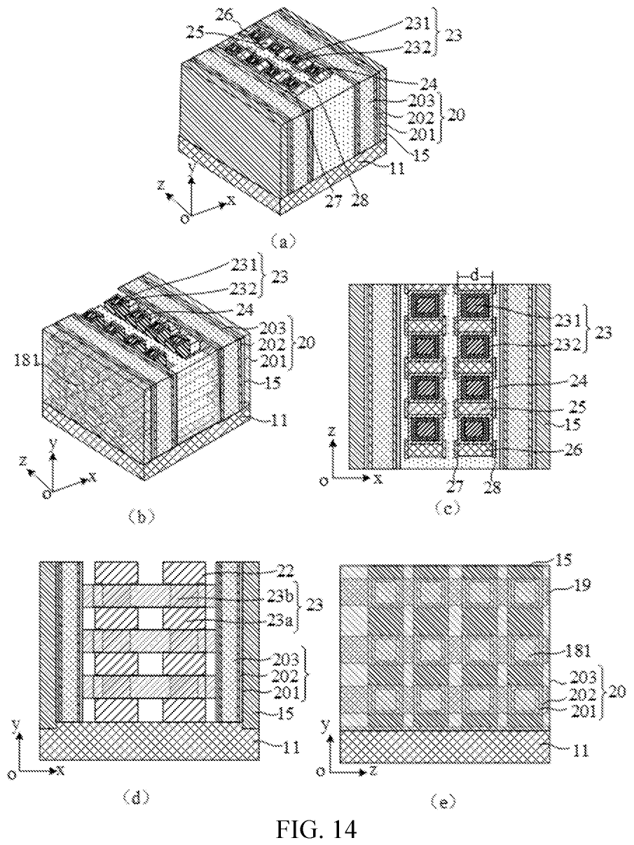

As an example, with reference to FIG. 14, forming the intermediate channel layer in step S831 includes following steps:
Step S8311: removing parts of the initial channel layer 24 located on opposite sides of the horizontal portion 23a in the first direction (for example, the oz direction) to form a first trench 25 and a second trench 26 extending in the second direction (for example, the ox direction) in the target semiconductor pillar 18, wherein the first trench 25 and the second trench 26 are located on opposite sides of the gate conductive layer 231 in the first direction (for example, the oz direction), a distance between the first trench 25 and the second trench 26 in the first direction (for example, the oz direction) is less than a length of the horizontal portion 23a in the first direction (for example, the oz direction) and greater than a length of the protrusion portion 23b in the first direction (for example, the oz direction). The remaining initial channel layer 24 forms the intermediate channel layer.

In step S8311, with continued reference to FIG. 14, since the gate conductive layer 231 includes the gate horizontal portion and the gate protrusion portion having different width dimensions in the second direction (for example, the ox direction) and the first direction (for example, the oz direction), in the process of etching the first trench 25 and the second trench 26, the initial channel layer 24 covered on the surfaces on opposite sides of each horizontal portion 23a in the first direction (for example, the oz direction) can be directly removed to form the intermediate channel layer. This process step is simple and easy to implement at the process level, which can improve preparation efficiency.

It should be noted that, when the first trench 25 and the second trench 26 are formed to remove the initial channel layer 24 located on opposite sides of the gate horizontal portion in the second direction, the gate dielectric layer 232 located on opposite sides of the gate horizontal portion in the second direction may also be partially etched, and thus a region finally formed by the gate dielectric layer 232 is the target side surface of the gate conductive layer 231, and the target side surface includes at least the outer side wall of the gate protrusion portion.

As an example, with continued reference to FIG. 14, the target side surface is the outer side wall of the gate protrusion portion, or the outer side wall of the gate protrusion portion and at least a part of the outer surface of the gate horizontal portion. For example, the gate dielectric layer 232 is located on the outer side wall of the gate protrusion portion and on the outer surface of the gate horizontal portion except for the side walls on opposite sides in the first direction (for example, the oz direction). In other embodiments, the target side surface may also be the outer side wall of the gate protrusion portion, that is, the gate dielectric layer 232 is located only on the outer side wall of the gate protrusion portion. The target side surface may be the outer side wall of the gate protrusion portion and the entire outer surface of the gate horizontal portion.

As an example, with continued reference to FIG. 14, the first trench 25 and the second trench 26 are formed by a dry etching process, that is, the initial channel layer 24 covered on the surfaces on opposite sides of each horizontal portion 23a in the first direction (for example, the oz direction) is removed by a dry etching process to form an intermediate channel layer, thereby improving the preparation efficiency.

It should be noted that, in other embodiments, the target word line trench 22, the gate structure 23, and the initial channel layer 24 may also be formed before the initial semiconductor pillars 13 are formed, and then the step of forming the initial semiconductor pillars 13 to form the active regions may be combined with the step of forming the first trench 25 and the second trench 26, and performed simultaneously. The initial channel layer 24 on opposite sides of the gate horizontal portion in the first direction (for example, the oz direction) may be removed while forming the active regions, to form an intermediate channel layer (not shown in the figure). The above-described method can simplify the preparation steps by combining the dry etching for forming the initial semiconductor pillars 13 and the dry etching for forming the first trench 25 and the second trench 26 into one step, and can also improve the preparation efficiency of the semiconductor device 100.

As an example, with reference to FIG. 14, forming the target channel layer 29 in step S832 includes following steps:
Step S8321: forming a third trench 27 and a fourth trench 28 extending in the first direction (for example, the oz direction) in the dielectric portions 131 on opposite sides of the gate conductive layer 231 in the second direction (for example, the ox direction) to expose the intermediate channel layer located on opposite sides of the horizontal portion 23a in the second direction (for example, the ox direction); a spacing between the third trench 27 and the fourth trench 28 in the second direction (for example, the ox direction) is equal to a target spacing d, which is a spacing between outer side walls of the intermediate channel layer on the opposite sides of the horizontal portion 23a in the second direction (for example, the ox direction);
Step S8322: etching and removing part of the intermediate channel layer via the third trench 27 and the fourth trench 28, and forming the target channel layer 29 by the remaining intermediate channel layer.

In step S8321, with continued reference to FIG. 14, the third trench 27 and the fourth trench 28 extending in the first direction (for example, the oz direction) are formed in the dielectric portions 131 on opposite sides of the gate conductive layer 231 in the second direction (for example, the ox direction) via the first trench 25 and the second trench 26 that have been formed before, so as to expose the intermediate channel layer located on the opposite sides of the horizontal portion 23a in the second direction (for example, the ox direction), so that in a subsequent etching process, the exposed intermediate channel layer can be directly etched to remove a part of the intermediate channel layer.

As an example, with continued reference to FIG. 14, the first trench 25, the second trench 26, the third trench 27, and the fourth trench 28 may be interconnected.

It should be noted that, in other embodiments, with continued reference to FIG. 14, the first trench 25, the second trench 26, the third trench 27, and the fourth trench 28 may be formed simultaneously, and after the above four trenches are formed, the initial channel layer on opposite sides of the horizontal portion 23a in the first direction (for example, the oz direction) and opposite sides of the horizontal portion 23a in the second direction (for example, the ox direction) are removed by dry etching or wet etching to obtain the target channel layer 29.

As an example, with continued reference to FIG. 14, the third trench 27 and the fourth trench 28 are formed by a dry etching process, and a part of the intermediate channel layer is etched and removed via the third trench 27 and the fourth trench 28 by a wet etching process.

In step S8322, with continued reference to FIG. 14, the third trench 27 and the fourth trench 28 are formed by a dry etching process. A part of the intermediate channel layer is etched and removed through the third trench 27 and the fourth trench 28 by a wet etching process. Specifically, in the wet etching process, an etching liquid that only reacts with the material of the intermediate channel layer can be used and put into the third trench 27 and the fourth trench 28 to etch the exposed intermediate channel layer, thereby removing the channel layer material on the opposite sides of the gate horizontal portion in the first direction (for example, the oz direction) to form the target channel layer 29. Therefore, the preparation method employed in the present application can remove part of the channel layer material by a combination of dry etching and wet etching, so that the target channel layer 29 does not cover the surfaces on opposite sides of the horizontal portion 23a in the second direction (for example, the ox direction) and surfaces on opposite sides of the horizontal portion 23a in the first direction (for example, the oz direction), and simplifies the preparation process while disconnecting the upper and lower layers of transistors, which can not only avoids generation of parasitic transistors, but also improve the preparation efficiency and yield of the memory 1000.

As an example, with reference to FIGS. 15-16, bit line structures 32 are further formed at second ends of the conductive portions 181 opposite to the first ends in the second direction (e.g., the ox direction), the conductive portions 181 adjacent in the first direction (e.g., the oz direction) share the bit line structure 32, and bit line structures 32 adjacent in the thickness direction (e.g., the oy direction) are insulated from each other. Common bit lines 33 are further formed at a side of the bit line structures 32 in the first direction (for example, the oz direction), the common bit lines 33 extend in the second direction (for example, the ox direction), and common bit lines 33 adjacent in the thickness direction (for example, the oy direction) are insulated from each other.

As an example, with continued reference to FIGS. 15-16, after the target word line structure is formed in step S8, the method further includes following steps.
Step S9: forming a metal contact layer 31 on the top of the capacitor structure 20, the top of the target word line structure, and the top of a common bit line 33.

In step S9, with continued reference to FIGS. 14 and 16, after the target channel layer 29 is formed, a third isolation structure 30 is formed inside the first trench 25, the second trench 26, the third trench 27, and the fourth trench 28. Specifically, a material of the third isolation structure 30 may be the same as a material of the first isolation structure 14, the second isolation structure 19, and the dielectric portion 131. Then, the metal contact layer 31 is formed on the top of the capacitor structure 20, the top of the target word line structure, and the top of the common bit line 33, and the metal contact layer 31 is electrically connected to each of the capacitor structure 20, the target word line structure, and the common bit line 33 as a metal lead.

As an example, with continued reference to FIG. 16, another aspect of the present application provides a semiconductor device 100, which is prepared by the method for preparing the semiconductor device 100 described in any one of the embodiments of the present application, and the semiconductor device 100 includes a substrate 11, a plurality of target semiconductor pillars 18 arranged in a first direction (for example, the oz direction), and a target word line structure. One of the target semiconductor pillars 18 includes dielectric portions 131 and conductive portions 181 which are alternately stacked in a thickness direction (for example, the oy direction) of the substrate 11. One of the dielectric portions 131 is adjacent to the substrate 11, the target word line structure is located within a target semiconductor pillar 18 and its bottom surface is adjacent to the substrate 11.

In the semiconductor device 100 in the above-described embodiment, the semiconductor device 100 prepared by the preparation method described in any one of the embodiments of the present application includes a substrate 11, target semiconductor pillars 18 and a target word line structure, wherein the target semiconductor pillars 18 include dielectric portions 131 and conductive portions 181 alternately stacked in the thickness direction of the substrate 11 (e.g., the oy direction), thus overall performance of the semiconductor device 100 can be improved to improve the yield of the vertical oxide channel 3D DRAM device while saving costs.

As an example, with continued reference to FIG. 16, sides of the conductive portions 181 in the second direction (for example, the ox direction) exceed sides of the dielectric portions 131 in the second direction (for example, the ox direction). The second direction (e.g. the ox direction) intersects the first direction (for example, the oz direction). The semiconductor device 100 further includes a support layer 15 located on a surface on a side of the target semiconductor pillars 18 in the second direction (for example, the ox direction) to support the conductive portions 181, thereby improving the yield of the semiconductor device 100.

As an example, with continued reference to FIG. 16, a material of the dielectric portions 131 includes an oxide, and a material of the conductive portions 181 is selected from copper, tungsten, aluminum, copper alloy, and combinations thereof.

As an example, with continued reference to FIG. 16, the target word line structure includes a plurality of gate structures 23 arranged sequentially in the thickness direction (e.g., the oy direction). One of the gate structures 23 includes a protrusion portion 23b and a horizontal portion 23a connected to a bottom surface of the protrusion portion 23b. The protrusion portion 23b penetrates through the conductive portion 181 directly above it in the thickness direction of the conductive portion 181 (for example, the oy direction), and the horizontal portion 23a is located between conductive portions 181 adjacent in the thickness direction (for example, the oy direction) and connected to the protrusion portion 23b directly above it.

As an example, the semiconductor device 100 further includes a target channel layer 29 that circumferentially surrounds an outer side wall of the protrusion portion 23b.

As an example, with continued reference to FIG. 16, the target channel layer 29 may be located on a target surface of the horizontal portion 23a, and the target surface is an outer surface of the horizontal portion 23a except for the outer side wall.

In the semiconductor device 100 in the above embodiment, the target channel layer 29 does not cover the side surface of the horizontal portion 23a in the gate structure 23, that is, the target channel layer 29 is not formed on surfaces on opposite sides in the second direction (for example, the ox direction) and surfaces on opposite sides in the first direction (for example, the oz direction) of the horizontal portion 23a, and the target channel layer 29 is formed on the side wall of the protrusion portion 23b. Therefore, the protrusion portion 23b in the gate structure 23 and the target channel layer 29 are used to form a same transistor. When a plurality of gate structures 23 are stacked in the thickness direction (for example, the oy direction), a horizontal portion 23a of one gate structure 23 is electrically connected to a protrusion portion 23b of an adjacent gate structure 23. However, since the sidewall of the horizontal portion 23a between the two adjacent protrusion portions 23b is not covered by the target channel layer 29, connection between two adjacent transistors of the upper and lower layers is disconnected, and there is no parasitic transistor between the transistors. The present application optimizes the preparation process of vertical oxide channel 3D DRAM devices, while also removing the channel material between two adjacent transistors in the thickness direction (such as the oy direction) in the device, and retaining the channel material on the transistor sidewall, thereby avoiding the generation of parasitic transistors between transistors, reducing leakage current, improving the operational efficiency of transistors, and enhancing the yield of vertical oxide channel devices.

As an example, with continued reference to FIG. 16, the bottom surface of the protrusion portion 23b is located in the middle of the top surface of the horizontal portion 23a, and a length of the protrusion portion 23b in the second direction (for example, the ox direction) is smaller than a length of the horizontal portion 23a in the second direction (for example, the ox direction), a length of the protrusion portion 23b in the first direction (e.g. the oz direction) is smaller than a length of the horizontal portion 23a in the first direction (e.g. the oz direction), and the target channel layer 29 does not cover the sidewall of the horizontal portion 23a, thereby breaking the electrical connection between two gate structures 23 or transistors adjacent in the thickness direction (for example, the oy direction).

As an example, with continued reference to FIG. 16, a thickness of the horizontal portion 23a is greater than the length of the protrusion portion 23b in the second direction (e.g., the ox direction) to increase the spacing between two transistors adjacent in the thickness direction (e.g., the oy direction) and further reduce parasitic transistors.

As an example, with continued reference to FIG. 16, a thickness of the horizontal portion 23a is greater than the length of the protrusion portion 23b in the first direction (e.g., the oz direction) to increase the spacing between two transistors adjacent in the thickness direction (e.g., the oy direction) and further reduce parasitic transistors.

As an example, with continued reference to FIG. 16, the gate structure 23 includes a gate conductive layer 231 and a gate dielectric layer 232. The gate conductive layer 231 includes a gate protrusion portion and a gate horizontal portion. The gate dielectric layer 232 is located on a target side surface of the gate conductive layer 231, and the target side surface includes at least an outer side wall of the gate protrusion portion.

As an example, with continued reference to FIG. 16, the target side surface is the outer side wall of the gate protrusion portion, or the outer side wall of the gate protrusion portion and at least a part of the outer surface of the gate horizontal portion. For example, the gate dielectric layer 232 is located on the outer side wall of the gate protrusion portion and on the outer surface of the gate horizontal portion except for the side walls on opposite sides in the first direction (for example, the oz direction). In other embodiments, the target side surface may also be the outer side wall of the gate protrusion portion, that is, the gate dielectric layer 232 is located only on the outer side wall of the gate protrusion portion. The target side surface may also be the outer side wall of the gate protrusion portion and the entire outer surface of the gate horizontal portion.

As an example, with continued reference to FIG. 16, a material of the gate conductive layer 231 is selected from indium tin oxide, polysilicon, copper, tungsten, aluminum, copper alloy, titanium, titanium nitride, yttrium nitride, tantalum nitride, and combinations thereof. In this embodiment, the material of the gate conductive layer 231 is indium tin oxide, that is, ITO (Indium Tin Oxide) thin film, and the ITO film can have suitable shielding efficiency in the range of 150 KHz to 1 GHz, and has stronger light transmittance than that of ordinary grid material shielding glass.

As an example, with continued reference to FIG. 16, a material of the gate dielectric layer 232 is selected from hafnium dioxide, zirconium dioxide, titanium dioxide, aluminum oxide, and combinations thereof. The gate dielectric layer 232 may be one or more of other high dielectric constant materials, wherein the high dielectric constant material is a material having a dielectric constant greater than or equal to 3.9, or a material having a dielectric constant greater than or equal to the dielectric constant of silicon dioxide.

As an example, with continued reference to FIG. 16, a material of the target channel layer 29 is selected from indium gallium zinc oxide, indium zinc oxide, transition metal, transition metal oxide, and combinations thereof. In the present embodiment, the material of the target channel layer 29 is indium gallium zinc oxide, that is, IGZO (Indium Gallium Zinc Oxide), which is a channel layer material used in a new generation thin film transistor technology and is a type of metal oxide (Oxide) panel technology.

As an example, with continued reference to FIG. 16, the semiconductor device 100 further includes a capacitor structure 20 located at the first ends of the conductive portions 181 in the second direction (e.g., the ox direction) and between the support layer 15 and the target semiconductor pillars 18, and surrounding the conductive portions 181.

As an example, with continued reference to FIG. 16, the capacitor structure 20 includes a first electrode layer 201, an intermediate dielectric layer 202 and a second electrode layer 203. The first electrode layer 201 surrounds outer side walls of the conductive portions 181 between the support layer 15 and the target semiconductor pillars 18, the intermediate dielectric layer 202 surrounds an outer side wall of the first electrode layer 201, and the second electrode layer 203 surrounds an outer side wall of the intermediate dielectric layer 202, and fills up a gap between the support layer 15 and the target semiconductor pillars 18.

As an example, with continued reference to FIG. 16, the semiconductor device 100 further includes bit line structures 32 and common bit lines 33. The bit line structures 32 are located at second ends of the conductive portions 181 in the second direction (for example, the ox direction) and extend in the first direction (for example, the oz direction), conductive portions 181 adjacent in the first direction (for example, the oz direction) share a bit line structure 32, and bit line structures 32 adjacent in the thickness direction (for example, the oy direction) are insulated from each other. The common bit lines 33 is located at a side of the bit line structures 32 in the first direction (for example, the oz direction) and extend in the second direction (for example, the ox direction), and common bit lines 33 adjacent in the thickness direction (for example, the oy direction) are insulated from each other.

As an example, with continued reference to FIG. 16, the semiconductor device 100 further includes a metal contact layer 31 located on the top of the capacitor structure 20, the top of the target word line structure, and the top of a common bit line 33, and the metal contact layer 31 is electrically connected to each of the capacitor structure 20, the target word line structure, and the common bit line 33 as a metal lead.

As an example, with continued reference to FIG. 16, another aspect of the present application provides a memory 1000 including two semiconductor devices 100 according to any one of the embodiments of the present application adjacent in the second direction (e.g., the ox direction). Two semiconductor devices 100 adjacent in the second direction (for example, the ox direction) share a bit line structure 32.

In the memory 1000 in the above-described embodiment, by using two semiconductor devices 100 according to any one of the embodiments of the present application adjacent in the second direction (for example, the ox direction), overall performance of the semiconductor devices 100 can be improved while saving costs, to improve the yield of the vertical oxide channel 3D DRAM device. In addition, by using the memory 1000 as described in the embodiment of the present application, electrical connection between two adjacent transistors in the thickness direction (for example, the oy direction) can be broken, thereby avoiding the generation of parasitic transistors between the two adjacent transistors, and thus reducing the leakage current of a device where the memory 1000 is located.

As an example, another aspect of the present application provides an electronic device including the memory 1000 according to any one of the embodiments of the present application.

The electronic device in the above embodiment not only reduces the etching difficulty in the preparation process, but also improves the etching efficiency. Even parasitic transistors between two target unit structures adjacent in the thickness direction can be avoided to reduce the leakage current of the vertical oxide channel DRAM device, thereby improving the yield and working efficiency of the electronic device.

Please note that the above embodiments are for illustrative purposes only and are not meant to be limiting the present application.

It should be understood that, unless explicitly stated herein, there is no strict order in which the steps described can be performed, and they can be performed in other orders. Furthermore, at least some of the steps described may include a plurality of sub-steps or stages, and these sub-steps or stages are not necessarily executed and completed at the same time, but can be executed at different times, and the order in which these sub-steps or stages are executed is not necessarily sequential, instead, they can be executed in turn or alternatively with other steps or at least some of sub-steps or stages of other steps.

Each embodiment in the present specification is described in a progressive manner, with each embodiment highlighting differences from other embodiments, and the same and similar parts between the embodiments may be cross-referenced.

The various technical features of the above-described embodiments can be arbitrarily combined, and for the sake of brevity of description, not all possible combinations of the individual technical features of the above-described embodiments have been described. However, as long as there is no conflict in these combinations of technical features, they should be considered to be within the scope of the present specification.

The above-described examples merely express a few of the implementations of the present application, and the description thereof is relatively specific and detailed, but should not be understood as limiting the scope of the patent application. It should be noted that for those of ordinary skills in the art, several modifications and improvements can be made without departing from the concept of the present application, and these modifications and improvements are all within the scope of protection of the present application. Therefore, the scope of protection of this patent application should be subject to the attached claims.

1. A method for preparing a semiconductor device, comprising:
providing a substrate and forming a stacked structure on the substrate, wherein the stacked structure comprises dielectric layers and sacrificial layers alternately stacked in a thickness direction of the substrate, and one of the dielectric layers is adjacent to the substrate;
forming a plurality of initial semiconductor pillars arranged at intervals in a first direction based on the stacked structure, and forming a plurality of reference word line trenches arranged at intervals in the first direction; wherein an initial semiconductor pillar of the plurality of initial semiconductor pillars comprises dielectric portions and sacrificial portions alternately stacked in the thickness direction, and a reference word line trench of the plurality of reference word line exposes a part of the substrate;
removing the sacrificial portions and replacing the sacrificial portions with conductive portions; wherein the dielectric portions and the conductive portions alternately stacked in the thickness direction are used to form a target semiconductor pillar; and
forming a target word line trench based on the reference word line trench to form a target word line structure within the target word line trench.

2. The method for preparing the semiconductor device according to claim 1, wherein the initial semiconductor pillar extends in a second direction, the second direction intersects the first direction, and forming the initial semiconductor pillars and the reference word line trenches comprises:
forming the plurality of initial semiconductor pillars arranged at intervals in the first direction based on the stacked structure;
laterally etching the initial semiconductor pillar in the second direction such that sides of the sacrificial portions in the second direction exceed sides of the dielectric portions in the second direction;
forming a support layer on surfaces of the initial semiconductor pillars in the second direction; and
forming the reference word line trenches within the initial semiconductor pillars.

3. The method for preparing the semiconductor device according to claim 1, wherein forming the initial semiconductor pillars and the reference word line trenches comprises:
forming the plurality of reference word line trenches arranged in the first direction within the stacked structure;
laterally etching the stacked structure in a second direction such that sides of the sacrificial layers in the second direction exceed sides of the dielectric layers in the second direction;
forming a support layer on a surface on a side of the stacked structure in the second direction; and
forming the plurality of initial semiconductor pillars arranged at intervals in the first direction based on the stacked structure, wherein the reference word line trenches are located within the initial semiconductor pillars, and the second direction intersects the first direction.

4. The method for preparing the semiconductor device according to claim 1, wherein a material of the dielectric portions comprises an oxide, a material of the sacrificial portions is selected from nitride, polysilicon, and combinations thereof, and a material of the conductive portions is selected from copper, tungsten, aluminum, copper alloy, and combinations thereof.

5. The method for preparing the semiconductor device according to claim 1, wherein a word line material layer is formed in the reference word line trench, and forming the target word line trench further comprises:
removing the word line material layer; and
etching the dielectric portions and the conductive portions in the first direction and the second direction via the reference word line trench to form the target word line trench, wherein the target word line trench comprises a plurality of gate trenches which are arranged in sequence in the thickness direction and interconnected.

6. The method for preparing the semiconductor device according to claim 5, wherein forming the target word line structure comprises:
sequentially forming gate structures and a target channel layer in the gate trenches, wherein the target word line structure comprises a plurality of the gate structures arranged in sequence in the thickness direction;
a gate structure of the plurality of gate structures comprises a protrusion portion and a horizontal portion connected to a bottom surface of the protrusion portion, the protrusion portion penetrates through a conductive portion directly above the protrusion portion in the thickness direction, the horizontal portion is positioned between conductive portions adjacent in the thickness direction and connected to the protrusion portion directly above the horizontal portion, and the target channel layer circumferentially surrounds an outer side wall of the protrusion portion.

7. The method for preparing the semiconductor device according to claim 6, wherein the gate structure comprises a gate conductive layer and a gate dielectric layer, and the gate conductive layer comprises a gate protrusion portion and a gate horizontal portion, the gate dielectric layer is located on a target side surface of the gate conductive layer, and the target side surface comprises at least an outer side wall of the gate protrusion portion.

8. The method for preparing the semiconductor device according to claim 7, wherein an inner surface of the target word line trench is further covered by an initial channel layer, and forming the target channel layer comprises:
removing parts of the initial channel layer located on opposite sides of the horizontal portion in the first direction, and forming an intermediate channel layer by remaining initial channel layer; and
removing parts of the intermediate channel layer located on opposite sides of the horizontal portion in the second direction, and forming the target channel layer by remaining intermediate channel layer, wherein the second direction intersects the first direction.

9. The method for preparing the semiconductor device according to claim 8, wherein forming the intermediate channel layer comprises:
forming a first trench and a second trench extending in the second direction in the stacked structure, and removing the parts of the initial channel layer located on opposite sides of the horizontal portion in the first direction, wherein the first trench and the second trench are located on opposite sides of the gate conductive layer in the first direction, a distance between the first trench and the second trench in the first direction is smaller than a length of the horizontal portion in the first direction and larger than a length of the protrusion portion in the first direction, and remaining initial channel layer forms the intermediate channel layer; or
wherein forming the target channel layer comprises:
forming a third trench and a fourth trench extending in the first direction in dielectric portions on opposite sides of the gate conductive layer in the second direction to expose the intermediate channel layer on opposite sides of the horizontal portion in the second direction; a spacing between the third trench and the fourth trench in the second direction is equal to a target spacing, and the target spacing is a spacing between outer side walls of the intermediate channel layer on opposite sides of the horizontal portion in the second direction; and
etching and removing a part of the intermediate channel layer via the third trench and the fourth trench, and forming the target channel layer by remaining intermediate channel layer.

10. The method for preparing the semiconductor device according to claim 9, wherein the first trench and the second trench are formed by a dry etching process.

11. (canceled)

12. The method for preparing the semiconductor device according to claim 9, wherein the third trench and the fourth trench are formed by a dry etching process, and the part of the intermediate channel layer is etched and removed via the third trench and the fourth trench using a wet etching process.

13. The method for preparing the semiconductor device according to claim 1, wherein after forming the conductive portions and before forming the target word line trench, the method further comprises:
forming a capacitor structure at first ends of the conductive portions in the second direction, wherein the capacitor structure surrounds the conductive portions; and
bit line structures are further formed at second ends of the conductive portions opposite to the first ends in the second direction, conductive portions adjacent in the first direction share a bit line structure, and bit line structures adjacent in the thickness direction are insulated from each other; common bit lines are further formed at sides of the bit line structures in the first direction, the common bit lines extend in the second direction, and common bit lines adjacent in the thickness direction are insulated from each other; after forming the target word line structure, the method further comprises:
forming a metal contact layer on a top of the capacitor structure, a top of the target word line structure, and a top of a common bit line.

14. (canceled)

15. A semiconductor device prepared by the method for preparing the semiconductor device according to claim 1, wherein the semiconductor device comprises:
a substrate;
a plurality of target semiconductor pillars arranged in a first direction, a target semiconductor pillar of the plurality of target semiconductor pillars comprises dielectric portions and conductive portions alternately stacked in a thickness direction of the substrate, and one of the dielectric portions is adjacent to the substrate; and
a target word line structure located within the target semiconductor pillar and having a bottom surface adjacent to the substrate.

16. The semiconductor device according to claim 15, wherein sides of the conductive portions in the second direction exceed sides of the dielectric portions in the second direction, and the second direction intersects the first direction; the semiconductor device further comprises:
a support layer located on surfaces of the target semiconductor pillars in the second direction; or
wherein a material of the dielectric portions comprises an oxide, a material of the conductive portions is selected from copper, tungsten, aluminum, copper alloy, and combinations thereof; or
wherein the target word line structure comprises a plurality of gate structures arranged in sequence in the thickness direction; a gate structure of the plurality of gate structures comprises a protrusion portion and a horizontal portion connected to a bottom surface of the protrusion portion, wherein the protrusion portion penetrates through a conductive portion directly above the protrusion portion in a thickness direction of the conductive portion, and the horizontal portion is positioned between conductive portions adjacent in the thickness direction and connected to the protrusion portion directly above the horizontal portion; or
the semiconductor device further comprises:
a capacitor structure surrounding the conductive portions.

17. (canceled)

18. (canceled)

19. The semiconductor device according to claim 16, further comprising:
a target channel layer circumferentially surrounding an outer side wall of the protrusion portion; and
wherein a bottom surface of the protrusion portion is located in a middle of a top surface of the horizontal portion; and
wherein a thickness of the horizontal portion is greater than a length of the protrusion portion in the second direction, and/or a thickness of the horizontal portion is greater than a length of the protrusion portion in the first direction.

20. (canceled)

21. (canceled)

22. The semiconductor device according to claim 19, wherein the gate structure comprises a gate conductive layer and a gate dielectric layer, and the gate conductive layer comprises a gate protrusion portion and a gate horizontal portion; and
the gate dielectric layer is located on a target side surface of the gate conductive layer, and the target side surface comprises at least an outer side wall of the gate protrusion portion.

23. The semiconductor device according to claim 22, wherein the target side surface is:
an outer side wall of the gate protrusion portion; or
an outer side wall of the gate protrusion portion, and at least a part of an outer surface of the gate horizontal portion;
or,
the semiconductor device comprises at least one of the following:
a material of the gate conductive layer is selected from indium tin oxide, polysilicon, copper, tungsten, aluminum, copper alloy, titanium, titanium nitride, yttrium nitride, tantalum nitride, and combinations thereof;
a material of the gate dielectric layer is selected from hafnium dioxide, zirconium dioxide, titanium dioxide, aluminum oxide, and combinations thereof; and
a material of the target channel layer is selected from indium gallium zinc oxide, indium zinc oxide, transition metal, transition metal oxide, and combinations thereof.

24. (canceled)

25. (canceled)

26. The semiconductor device according to claim 16, further comprising:
bit line structures located at second ends of the conductive portions in the second direction and extending in the first direction, wherein conductive portions adjacent in the first direction share a bit line structure, and bit line structures adjacent in the thickness direction are insulated from each other;
common bit lines located at a side of the bit line structures in the first direction and extending in the second direction, wherein common bit lines adjacent in the thickness direction are insulated from each other; and
a metal contact layer located on a top of the capacitor structure, on a top of the target word line structure, and on a top of a common bit line.

27. (canceled)

28. (canceled)

29. A memory comprising:
two semiconductor devices according to claim 15 adjacent in a second direction, wherein the two semiconductor devices adjacent in the second direction share a bit line structure.

30. An electronic device comprising:
the memory according to claim 29.
